(19) United States
(12) Patent Application Publication
(10) Pub. No.: US 2010/0047588 A1
(43) Pub. Date: Feb. 25, 2010

(54) Electronic Component Union, Electronic Circuit Module Utilizing the Same, and Process for Manufacturing the Same

(76) Inventors: Syohei Hata, Yokohama (JP); Eiji Sakamoto, Yokohama (JP); Naoki Matsushima, Yokohama (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/295,767

(22) PCT Filed: Apr. 4, 2007
(86) PCT No.: PCT/JP2007/057546

§ 371 Date: Sep. 30, 2009

(30) Foreign Application Priority Data
Apr. 4, 2006 (JP) 206-102986

(51) Int. Cl. B32B 17/06; H01L 23/12

(52) U.S. Cl. 428/428; 156/273.9; 428/426; 428/432

(57) ABSTRACT

A technique for bonding a glass plate to an insulating material or a nonoxidized semiconductor substrate such as SiC without a bonding agent is provided. A metallized layer is formed on the insulating material or the nonoxidized semiconductor substrate such as SiC serving as a first substrate, and the metallized layer of the first substrate is bonded to a second glass substrate, which serves as a second substrate and contains ions capable of being diffused by a voltage, by anodic bonding.

### FIELD OF THE INVENTION

The present invention relates to an electronic component union, an electronic circuit module utilizing the same, and a process for manufacturing the same, and in particular, to an electronic component union which is suitable for a field in which, for example, optical components are mounted or a field where nonoxidized semiconductors such as SiC are mounted, an electronic circuit module utilizing the same, and a process for manufacturing the same.

### BACKGROUND OF THE INVENTION

Generally, solder or an adhesive to bond electronic components is used. In the case of solder, for example, when components do not directly get wet with solder, a conductive film is formed on a surface of each component and the components are bonded by solder. In the case of an adhesive, the adhesive is applied to parts to be bonded and components are pressed to bond them. These techniques are eminently suitable for bonding individual components, but may cause a problem such as formation of a non-bonded portion due to entrainment of voids when a wide area of a wafer or a plate-shaped component is bonded. Moreover, a bonding agent becomes a factor of a cost rise.

As a technique for bonding plate-shaped components such as wafers, there is a technique called anodic bonding. The anodic bonding is generally a technique for overlapping glass with a semiconductor such as Si or a conductor and directly bonding them, and is recently often used especially to bond glass and a silicon wafer, which is a semiconductor. In particular, the anodic bonding is used in an MEMS (Micro Electro Mechanical Systems) field, in which silicon is processed by etching to manufacture various kinds of sensors and components.

In the anodic bonding, generally, glass and silicon overlap each other and are heated to several hundreds of degrees. In this state, a negative electrode on the top surface of the glass and a positive electrode on the bottom surface of the silicon are brought into contact with each other, and a high voltage is applied. In this case, since Si can be almost considered as a conductor, a strong electric field is generated in the glass so as to forcibly diffuse positive ions, which have a small atomic radius such as Na contained in the glass, to the negative electrode side. In particular, it is said that a depletion layer of positive ions such as Na+ is formed around the bond interface between the glass and the silicon. Electric charge becomes imbalanced in the positive ion depletion layer such that the depletion layer is negatively charged. As a result, a stronger electrostatic attraction force is generated around the bond interface. The electrostatic attraction force strongly sticks the glass and the silicon. At the same time, oxygen contained in the glass reacts with silicon to form oxide on a surface of the silicon, thereby obtaining a strong chemical bond. The following patent documents are exemplified in association with the anodic bonding technique.

[Patent Publication 1] Japanese Unexamined Patent Application Publication (Laid-Open) No. H10(1998)-259039

[Patent Publication 2] Japanese Unexamined Patent Application Publication (Laid-Open) No. 2004-262698

### SUMMARY OF THE INVENTION

In anodic bonding, it is impossible to bond glass with an insulating material such as ceramics, or a nonoxidized semiconductor such as SiC, instead of a semiconductor such as silicon or a conductor bonded with glass.

One of the reasons is that, even though glass and an insulating material such as ceramics overlaps each other and are heated and a high voltage is applied, an electric field is formed in the ceramics and an electric field in the glass weakens, which makes it difficult to diffuse positive ions contained in glass.

Another reason is that, even though a strong electric field is impressed across the glass such that diffusion of ions in the glass occurs, the ceramics or the nonoxidized semiconductor material does not react chemically with the glass in a surface thereof and thus chemical bond is not obtained. Therefore, anodic bonding is characterized as a technique of bonding glass with a conductor or glass with a nonoxidized semiconductor such as Si. Up to now, an investigation on application of anodic bonding of glass with an insulating material such as ceramics, or a nonoxidized semiconductor such as SiC has been hardly made at a research level. The present invention discloses a technique for bonding glass with an insulating material such as ceramics, or a nonoxidized semiconductor such as SiC by anodic bonding.

In order to achieve the object, according to the present invention, a conductive film is formed on a top surface of a first substrate. A substrate which contains an insulating material such as ceramics as a main component, or a nonoxidized semiconductor substrate which is made of a compound semiconductor such as, silicon carbide (SiC) semiconductor, a III-V group compound, or a II-VI group compound is used as the first substrate. A glass substrate that contains ions capable of being diffused by a voltage is used as a second substrate, the conductive film of the first substrate and the glass substrate serving as the second substrate are bonded by anodic bonding.

The conductive film of the first substrate is used as a positive electrode, a negative electrode is pressed against the top surface of the glass substrate which is the second substrate, and a high DC voltage is applied across both electrodes, which makes it possible to generate a strong electric field in the glass. Moreover, a metal used as a material of the conductive film formed on the first substrate is selected from metals such as aluminum, titanium, chromium, tungsten, molybdenum, hafnium, zirconium, vanadium, magnesium, and iron, and these metals react chemically with oxygen which is contained in the glass, which it makes to obtain a firm bond. Reaction behavior of the conductive film with oxygen contained in the glass will be described in the latter half of the embodiments.

According to the present invention, it is possible to bond glass with ceramics without using a bonding agent such as solder or an adhesive, which contributes to lowering the cost. If a bonding agent is used, there is fear that it runs over at the time of bonding so as to cause surrounding pollution, etc. However, such a problem does not occur since the conductive film and the glass are directly bonded. Moreover, the anodic bonding is suitable for bonding plate-shaped components such as wafers and can improve the productivity as compared to a case in which individual components are bonded. In addition, it becomes possible to create new electronic components, which have never existed before, by bonding glass with ceramics or glass with a nonoxidized semiconductor.

### BRIEF DESCRIPTION OF THE DRAWINGS

FIG. 1 is a cross sectional view illustrating a structure an electronic component union according to a First Embodiment of the present invention.

FIG. 2 is a cross sectional view illustrating a bonding process of the electronic component union according to the First Embodiment of the present invention.

FIG. 3 is a cross sectional view illustrating a bonding structure of an electronic component union according to a Second Embodiment of the present invention.

FIG. 4 is a cross sectional view illustrating a bonding structure of an electronic component union according to a Third Embodiment of the present invention.

FIG. 5 is a cross sectional view illustrating a bonding structure of an electronic component union according to a Fourth Embodiment of the present invention.

FIG. 6 is a perspective view illustrating a product state of an electronic component union (a sub-mount for mounting an optical device) according to a Fifth Embodiment of the present invention.

FIG. 7 is a perspective view illustrating a state in which an optical device is mounted on the electronic component union according to the Fifth Embodiment of the present invention.

FIG. 8 is a perspective view illustrating a mounting state of an electronic component union (a sub-mount for mounting an optical device) according to a Sixth Embodiment of the present invention.

FIG. 9 is a cross sectional view illustrating a mounting state of an electronic component union (an electronic circuit module) according to a Seventh Embodiment of the present invention.

### EXPLANATION OF REFERENCE NUMERALS AND SYMBOLS IN THE DRAWINGS

1 . . . Ceramic substrate
2 . . . Ti metallized layer
3 . . . Al metallized layer
4 . . . Glass substrate
5 . . . Heater-cum-positive electrode
6 . . . Negative electrode needle
7 . . . Through electrode
8 . . . Wiring line
9 . . . Glass substrate
10 . . . Si substrate
11 . . . Metallized electrode
12 . . . Thin film solder
13 . . . Reflective film
14 . . . Optical device
21 . . . Si
22 . . . Glass
23 . . . SiC
24 . . . Ti metallized layer
25 . . . Al metallized layer
26 . . . Electrode
27 . . . Substrate
28 . . . Electrode
29 . . . Wire boding
30 . . . Solder
31 . . . Metallized patterns
50 . . . Electronic circuit module

### DETAILED DESCRIPTION OF THE PREFERRED EMBODIMENTS

Hereinafter, embodiments of the present invention will be described in detail with reference to the accompanying drawings.

### First Embodiment

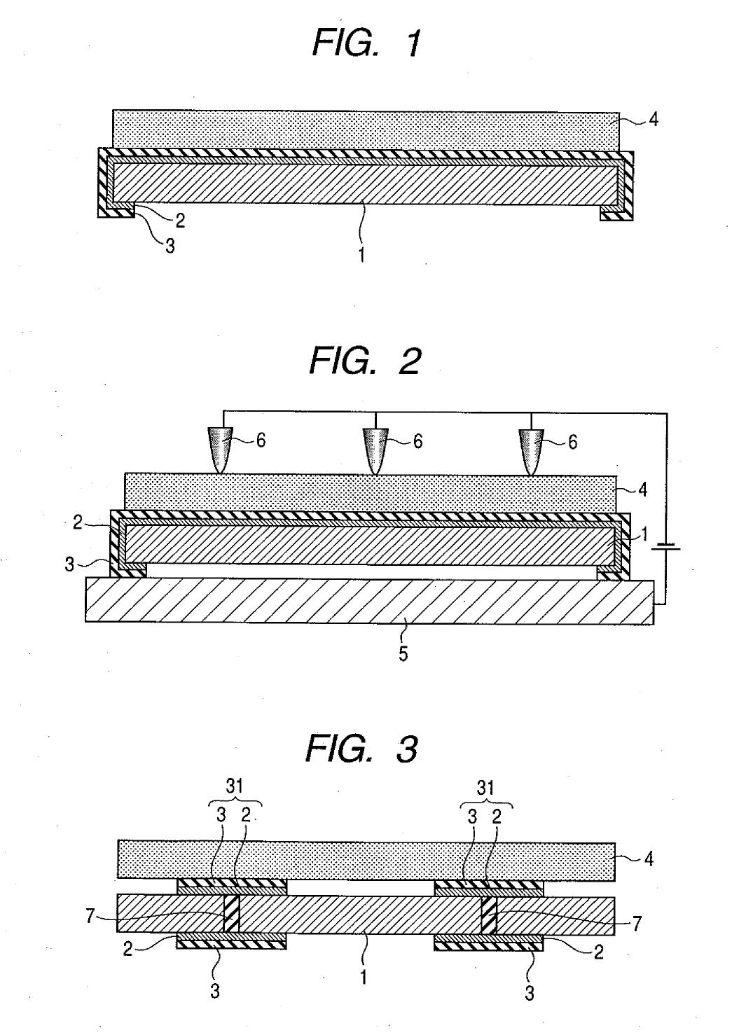

A first embodiment of the present invention will be described below with reference to FIG. 1. FIG. 1 is a cross sectional view of a union formed by bonding a ceramic substrate 1 to a glass substrate 4. A conductive film is formed on the ceramic substrate 1. The conductive film is composed of a Ti metallized layer 2 serving as an adhering layer and an Al metallized layer 3 serving as a bonding layer formed on the Ti metallized layer. Methods such as vacuum deposition or sputtering are suitable for forming each of the metallized layers. The bonding layer is provided to create a firm bond with the glass layer and the adhering layer is provided to create a firm bond of the bonding layer and the ceramic substrate 1. If the bonding layer is formed of a material that is a conductor and can be firmly bonded to the ceramic substrate 1, the adhering layer can be omitted.

In this embodiment, the metallized layer structure is formed of an accumulating layer of the adhering layer (Ti metallized layer) 2, which adheres to the ceramic substrate 1, and the bonding layer (Al metallized layer) 3. If the Ti metallized layer is extremely thin, it is impossible to obtain sufficient adherence property, and if the metallized layer is extremely thick, film stress due to contractile behavior after metallization increases. The film thickness may generally be about 0.05 to 0.2 μm and the moderate film thickness is 0.1 μm, etc. Moreover, if the Al metallized layer is extremely thin, it can not be formed as a complete film, and if the Al metallized layer is extremely thick, great unevenness results from grain growth. Sine Al transforms at the time of bonding, some unevenness is of no matter. The film thickness may generally be within a range of 0.1 μm to 3 μm (up to a maximum of about 10 μm) and is set to 0.1 μm in this embodiment.

The difference between a case where the adhering layer is provided and a case where any adhering layer is not provided is due to the adherence properties of various kinds of metallized layers to a substrate. For example, Ti or Cr exhibits an excellent adherence property with a ceramic substrate. Other metals may not necessarily exhibit sufficient adhesion properties. Therefore, in the case of Ti or Cr, it is possible to form a metallized layer directly on a ceramic substrate and to bond the metallized layer to a glass substrate by anodic bonding. This means that the Ti or Cr metallized layer serves as both of an adhering layer and a bonding layer.

It is preferable to form an adhering layer of Ti or Cr on a ceramic substrate in advance and then to form a metallized layer of another metal, that is, aluminum, tungsten, molybdenum, hafnium, zirconium, vanadium, magnesium, or iron.

In this embodiment, the Ti metallized layer 2 (0.1 ƒm) and the Al metallized layer 3 (1.0 μm) are formed on the ceramic substrate and the Al metallized layer 3 is bonded to the glass substrate 4 by anodic bonding.

FIG. 2 is a schematic diagram when the glass substrate 4 overlaps a main surface of the ceramic substrate 1 on which the conductive film has continuously been formed from the main surface to a peripheral portion of the back surface by accumulating the adhering layer (Ti metallized layer) 2 and the bonding layer (Al metallized layer) 3 as shown in the drawing, and is bonded to the ceramic substrate by anodic bonding. The Al metallized layer 3 is brought into contact with a heater-cum-positive electrode 5 of a bonding apparatus (not shown). Moreover, negative electrode needles 6 of the bonding apparatus is brought into contact with the glass substrate 4.

In this state, generally, the union is heated to 300° C. to 500° C. (400° C. in this embodiment) and several hundreds of high voltage or greater (practically, a DC voltage of 200 V to 1000 V) is applied across the heater-cum-positive electrode 5 and the negative electrode needles 6, so as to bond the bottom surface of the glass substrate 4 to the top surface of the Al metallized layer 3 by anodic bonding.

The feature of this bonding method is that it is possible to bond glass and ceramics, which are, for example, in a wafer state, by bonding the glass substrate 4 with the Ti/Al metallized layers formed on the ceramic substrate 1 by anodic bonding.

One of the conventional representative methods for bonding ceramics and glass is a method of forming a metallized layer on ceramics, form a metallized layer on a bonding surface of glass, and bonding both of the metallized layers by using solder. Another method is a method of bonding ceramics and glass by an adhesive. In the above-mentioned first method, there may be problems that wettability of solder may cause a void portion not to be bonded, and, if an amount of solder is large, the solder may overflow. In the case of using an adhesive, gas generation during hardening may become a problem, in addition to the void portion problem and the overflow problem.

For example, even though an attempt to bond a glass substrate and a ceramic substrate on which any metallized layer has not been formed by anodic bonding is made, the bonding is very difficult. The first reason is that both of the ceramic substrate and the glass substrate are insulating materials, and an electric field is formed even in the ceramic substrate and thus the electric field does not concentrate in the glass. For this reason, at the time of anodic bonding, positive ions such as Na⁺ contained in the glass substrate do not diffuse. As a result, a strong electrostatic attraction force cannot be generated around a bond interface, which makes it impossible to stick the ceramic substrate and the glass substrate together.

The second reason is that the surface of the ceramic substrate is made of a compound, which is chemically stable, and thus does not generally react with the oxygen contained in the glass even when being heated to several hundreds of degrees. For the above-mentioned reasons, the glass and the ceramic substrate cannot be firmly bonded to each other by anodic bonding even if both overlap each other, are heated, and a voltage is applied to them.

However, the structure according to this embodiment makes it possible to bond the ceramic substrate and the glass substrate by anodic bonding. As shown in FIG. 2, the Ti metallized layer 2 and the Al metallized layer 3 is formed on the sidewalls of the ceramic substrate 1 and a portion of the bottom surface of the ceramic substrate 1. Therefore, those conductive metallized layers are brought into contact with the heater-cum-positive electrode 5 such that the positive electrode 5 and the Al metallized layer 3 become substantially equipotential. If a high voltage is applied across the heater-cum-positive electrode 5 and the negative electrode needles 6, an electric field is intensively generated in the glass substrate 4. Therefore, the positive ions contained in the glass substrate are diffused and thus a strong electrostatic attraction force is generated in the bond interface such that the glass substrate 4 and the Al metallized layer 3 are stuck together. At the same time, the oxygen ions contained in the glass reacts with the Al metallized layer such that an Al oxide layer is formed at the surface of the Al metallized layer 3, whereby a strong bond is obtained. Moreover, Al may be ionized and diffused in the glass substrate 1.

As described above, the metallized layers are formed on the ceramic substrate, the glass substrate overlaps the ceramic substrate with the metallized layers interposed therebetween, and power is supplied to the metallized layers, whereby anodic bonding between the glass substrate and the ceramic substrate becomes possible.

Instead of the ceramic substrate 1 which is an insulating material, a nonoxidized semiconductor substrate such as SiC can be used. Even though an attempt to bond a SiC semiconductor and glass by anodic bonding is made, since reaction between SiC and oxygen contained in the glass is difficult, it is difficult to obtain a strong bond. However, it is possible to obtain a strong bond in a wafer state by anodic bonding by using a structure with interposing metallized layers according to this embodiment. This is similarly applied to even the following embodiments.

### Second Embodiment

A second embodiment of the present invention will be described with reference to FIG. 3. FIG. 3 shows a cross sectional view of main parts of a union. A feature of a structure according to this embodiment is that through electrodes 7 are formed in a ceramic substrate 1, and metallized patterns 31 are formed on both sides of the ceramic substrate and are electrically connected to each other. Even in this case, if the ceramic substrate 1 is disposed on the heater-cum-positive electrode 5 of the anodic bonding apparatus and a voltage is applied, similar to the first embodiment (refer to FIG. 2), the potential is substantially the same up to the Al metallized layer 3 which is a part bonded with the glass substrate 4. Therefore, if the negative electrode needles 6 of the anodic bonding apparatus are brought into contact with the glass substrate 4, an electric field concentrates in the glass substrate 4, which makes anodic bonding with the Al metallized layer 3 possible.

In forming the through electrodes 7 in the ceramic substrate 1, first, a resist mask pattern having openings corresponding to predetermined positions of the ceramic substrate 1 is formed, and through holes are formed through the ceramic substrate 1 by using a sandblasting method, etc. Next, the resist mask is removed, and a metallization process is performed to fill the inside of the through holes with a conductor by using plating, solder, conductive paste, etc. If necessary, finally, the surface of the ceramic substrate may be polished for polarization.

In order to form the metallized patterns 31 on the ceramic substrate 1 in which the through electrodes 7 have been formed, the following method can be used. First, a Ti metal thin film 2 and an Al metal thin film 3 are deposited to have thicknesses within a range of 0.05 μm to 0.2 μm and a range of 0.1 μm to 3 μm, respectively, (to have 0.1 μm and 1 μm respectively in this embodiment) by using a sputtering method, a deposition method, etc. Next, a resist pattern is formed by using a photolithographic method. Subsequently, a milling process or a wet etching process is performed.

A lift-off method can be applied as another method for forming the metallized patterns 31. According to the lift-off method, a resist pattern is formed in advance, metal thin films are deposited by using deposition, sputtering, etc., and unnecessary portions of the metal thin films are removed. Those methods of forming the through electrodes 7 and the metallized patterns 31 can be similarly applied to the following embodiments.

### Third Embodiment

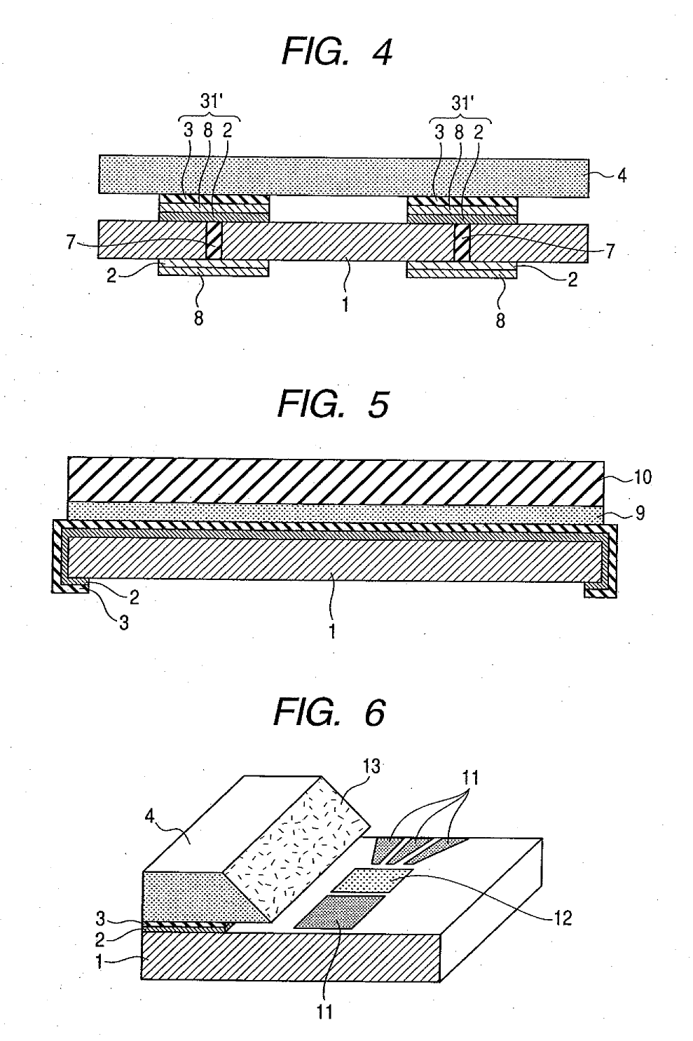

A third embodiment of the present invention will be described with reference to FIG. 4. A structure according to this embodiment is similar to that of the second embodiment except for a configuration of metallized patterns 31′ provided on a ceramic substrate 1. A Ti metallized layer 2 is formed as an adhering layer on the ceramic substrate 1 and wiring lines 8 are formed thereon. Moreover, an Al metallized layer 3 is formed on the side of surfaces, to be bonded with a glass substrate 1, of the wiring lines.

Various kinds of metallized structures, such as Ni/Au, Cu, Pt/Au, Pd/Au, Ag, Pd/Ag, etc., can be applied to the wiring lines 8.

This embodiment is designed in view of, for example, a structure in which a glass part is bonded to the ceramic substrate 1, on which the wiring lines have been formed, by anodic bonding. In this case, as described with respect to the second embodiment, it is possible to form the metallized layer, which is the bonding layer, on a portion of the surface of the ceramic substrate 1 on which the wiring lines 8 have not been formed. In this case, however, if the total thickness of the adhering layer and the bonding layer is equal to or less than the thickness of the wring lines, the wiring lines may interrupt anodic bonding of the bonding layer and the glass. This causes a large amount of metal to be used for the metallized layer which is the bonding layer, resulting in high cost. Therefore, in a case where a number of wiring lines 8 is formed on the ceramic substrate 1, if the Al metallized layer 3 is formed as the bonding layer on the wiring lines 8, even though the thickness of the Al metallized layer 3 is small, it is possible to perform anodic bonding with the glass. According to the structure of this embodiment, it is possible to bond optical elements, such as glass prisms, mirrors, lens having a rectangular contour, etc., to a ceramic substrate.

Even in such a structure, anodic bonding between the Al metallized layer 3 and the glass substrate 4 is possible by heating and voltage application, similar to the second embodiment.

### Fourth Embodiment

A fourth embodiment of the present invention will be described with reference to FIG. 5. FIG. 5 is a cross sectional view of a union which has basically the same structure as the first embodiment shown in FIG. 1, except for a structure of a glass substrate bonded to the ceramic substrate 1. In this embodiment, the glass substrate is not bonded to the ceramic substrate 1 by itself, but the glass substrate 9 and a Si substrate 10 are bonded by general anodic bonding in advance and then the glass substrate 9 is bonded to the Al metallized layer 3 formed on the ceramic substrate 1 by anodic bonding.

A structure represented by MEMS (Micro Electro Mechanical Systems), etc. may be formed in the Si substrate 10 by using an etching technique and then the Si substrate 10 may be bonded to the ceramic substrate 1 by anodic bonding. The metallized layers 2 and 3 on the ceramic substrate 1 are connected to the bottom surface of the ceramic substrate along the side surfaces thereof, similar to the first embodiment shown in FIG. 1. However, the metallized layers may be connected to the bottom surface of the ceramic substrate by through electrodes 7, similar to the second embodiment.

### Fifth Embodiment

A fifth embodiment of the present invention will be described with reference to FIG. 6. FIG. 6 is a perspective view illustrating an image of a part obtained by bonding the ceramic substrate 1 and the glass substrate 4 by anodic bonding as in the first embodiment, followed by cutting them into pieces.

The Ti metallized layer 2 and the Al metallized layer 3 are formed on the ceramic substrate 1. Moreover, metallized electrodes 11 and thin film solder 12 capable of being electrically connected by, for example, bonding fine wiring lines are formed.

In this embodiment, the glass substrate 4 is first cut into a strip shape and each section is polished so as to be at 45 degrees with respect to a surface of the glass substrate. The polished section is smoothly finished to become an optical reflective surface. Next, a reflective film 13 is formed on the polished section at 45 degrees with respect to the surface of the glass substrate.

The glass substrate 4 having the reflective film 13 and the Al metallized layer 3 on the ceramic substrate 1 are bonded by anodic bonding. As the anodic bonding method, the method described in the above-mentioned embodiments is applied. However, since cutting is performed after bonding in this embodiment, metallized side surfaces, through electrode parts, etc. are not shown in FIG. 6 illustrating an image of this embodiment. The Al metallized layer 3 is formed to extend, for example, from a side surface to a peripheral portion of a back surface of the ceramic wafer 1, together with the underlying Ti metallized layer 2, such that the Al metallized layer 3 surrounds the side surface and the peripheral portion of the back surface. Therefore, power can be supplied to the Al metallized layer 3 facing the glass substrate 9 during bonding.

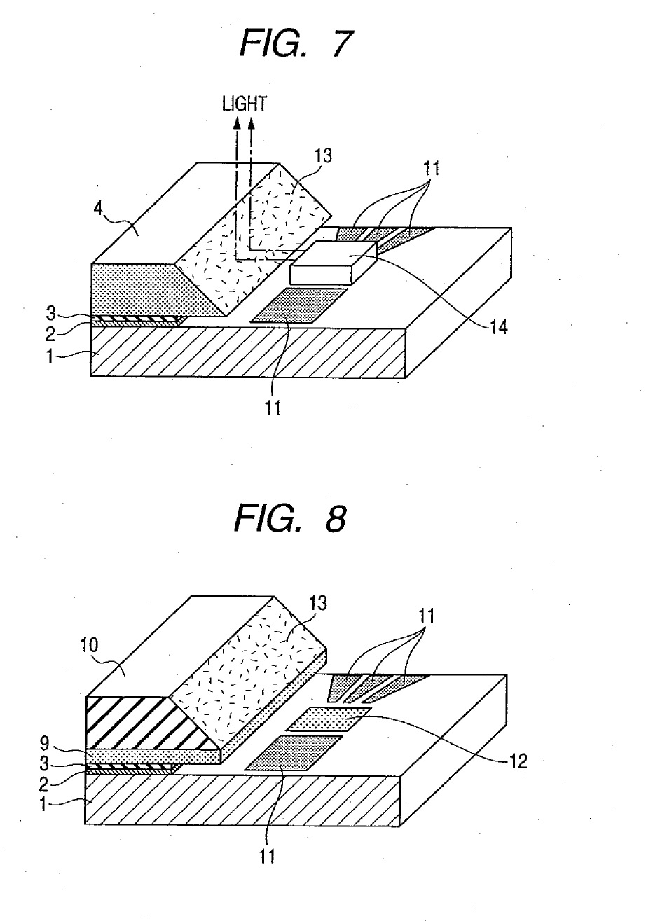

In this embodiment, the part shown in FIG. 6 (a sub-mount for mounting an optical device in this embodiment) is manufactured and then an optical device 14 is installed by using the metallized electrodes 11 and the thin film solder 12 as in FIG. 7, thereby making an electronic component having the optical device mounted thereon. In this case, the optical device 12 is a laser diode of an end surface light emitting type and light emitted from the optical device 12 is reflected from the reflective film 13 upwards. If a lens (not shown) is disposed above the optical device to focus the light, the electronic component can be used for optical communication, etc.

### Sixth Embodiment

A sixth embodiment of the present invention will be described with reference to FIG. 8. This embodiment is similar to the above-mentioned fifth embodiment except that a substrate obtained by bonding Si 10 and glass 9 is used as the second substrate. In this embodiment, a slope of the Si substrate 10 on which a reflective film 13 is formed is made by etching Si in a wafer state without polishing, unlike the fifth embodiment. Therefore, sub-mounts each having an optical device 14 mounted on thin film solder 12 are also manufactured in a wafer state, and FIG. 8 shows an image after the wafer is cut into components (sub-mounts) by dicing, etc.

First, the Si substrate 10 and the glass substrate 9 are bonded in advance by anodic bonding, as in the fourth embodiment. When a top surface of a Si wafer used is a (100) plane like general wafers, a surface appearing by subsequent wet etching becomes a (111) plane which is a close-packed plane, and a slope being at 54.7 degrees with respect to the (100) plane is formed. In order to form a slope tilted accurately at 45 degrees, a Si wafer whose surface and the (111) plane form 45 degrees is used. The Si substrate is bonded to the glass substrate by anodic bonding.

Next, a resist mask in which a portion corresponding to the slope formation portion of the surface of the Si substrate 10 is opened is formed by a photolithographic process. The (111) plane of Si is exposed by wet etching and a slope being at 45 degrees with respect to the surface of the wafer is formed. Since a number of through holes exist in the Si wafer and the glass substrate 9 remains on the bottom side of the holes, a mask is formed on the surface of the glass substrate and etching is performed by using fluorinated acid, etc., so as to remove the glass on the bottom side of the through holes of the Si substrate, thereby piercing both of Si and glass.

On the other hand, a Ti metallized layer 2, an Al metallized layer 3, and metallized electrodes 11 are formed on the ceramic substrate 1, similar to the fifth embodiment. Then, the glass substrate 9 and the Al metallized layer 3 are bonded together in a wafer state by anodic bonding. If a component is separated from the union by cutting, it becomes a state shown in the perspective view of FIG. 8.

### Seventh Embodiment

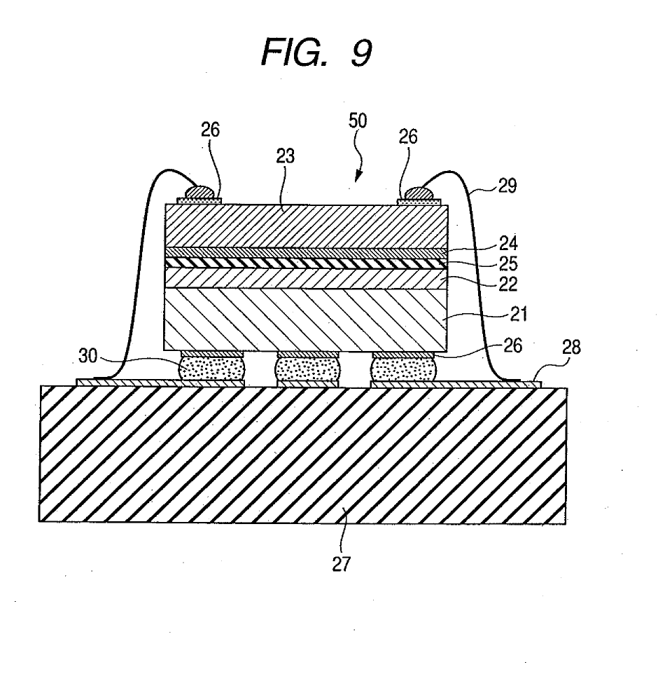

A seventh embodiment of the present invention will be described with reference to FIG. 9. This embodiment relates to a structure in which a SiC semiconductor 23 capable of operating at a high frequency and a Si semiconductor 21 are accumulated. FIG. 9 is a cross sectional view illustrating a state in which a Si semiconductor wafer 21 on which circuit elements have been formed and a SiC semiconductor wafer 23 have been joined together, and an electronic circuit module 50 has been separated from the union as one electronic component unit and mounted on a predetermined circuit substrate 27 by using solder 30. The circuit part was omitted in FIG. 9.

Glass 22 is bonded to the Si semiconductor 21 in advance by anodic bonding. This bonding is performed in a wafer state. The electronic circuits are formed on a surface of the Si wafer 21 by a semiconductor process. Moreover, electrodes 26 connected to the electronic circuits are formed on the same surface.

On the other hand, circuits and electrodes 26 are formed on the SiC semiconductor wafer 23 by a semiconductor forming process. An accumulating film of a Ti metallized layer 24 and an Al metallized layer 25 is formed on the surface opposite to the circuit forming surface of the SiC 23 by the same method as that in the first embodiment.

The Si 21 and the SiC 23 on which the circuits and the electrodes have been completely formed are bonded together by anodic bonding which is a feature of the present invention. More specifically, the glass 22 and the Al metallized layer 25 are bonded together by anodic bonding. It is possible to thicken the glass 22 according to the required characteristics. For example, thickening the glass may improve a heat insulating property between Si 21 and SiC 23. After Si 21 and SiC 23 are bonded together, an electronic circuit module 50 is separated from the union as one electronic component unit. This semiconductor component (electronic circuit module 50) is connected to electrodes 28 of a predetermined circuit substrate 27 prepared in advance by solder 30. Moreover, the electrodes 26 on SiC 23 are connected to the electrodes 28 on the substrate 27 by wire bonding 29. As a result, the circuits of the Si semiconductor 21 are connected to the circuits of the SiC semiconductor 23. Moreover, a small number of bumps due to the solder 30 are shown in FIG. 8 for simplification, but more bumps may be actually disposed.

In this embodiment, SiC 21 on one side may be mounted on the circuit substrate 27 by so-called face down bonding in which the circuit forming surface is faced downward and SiC 23 on the other side may be in a face up state in which the circuit forming surface is directed upward, and vice versa. In other words, SiC 23 may be mounted by face down bonding and SiC may be bonded in a face up state. For example, when SiC 23 is mounted by face down bonding, since SiC 23 is stronger than Si 21, resistance of SiC to chip crack around solder connection portion is high. Therefore, it is possible to use hard solder such as Au—Sn solder, etc., as the solder 30, for connecting to the substrate 27.

In this embodiment, accumulating the Si and SiC semiconductors has been described. However, if the technique of the present invention is used, accumulating SiC and SiC semiconductors is also possible. For this, a Ti metallized layer and an Al metallized layer are formed on one SiC substrate and the SiC substrate is bonded to a glass substrate in advance by anodic bonding. Next, circuits are formed and the SiC substrate is bonded to another SiC substrate by anodic bonding.

Moreover, in the embodiments, generally, a combination of Ti and Al metallized layers is used as a metallized layer of the other part side bonded to glass. However, the present invention is not limited thereto. It is possible to apply a Ti metallized layer, which has a high melting point and is resistant to corrosion, to a bonding part requiring a heat resisting property in particular.

In the present invention, a metal of a bonding layer bonded to glass by anodic bonding is selected from Al, Ti, Cr, W, Mo, Hf, Zr, V, Mg, and Fe. The reason will be describe below in detail.

First, the metal of the bonding layer is required to easily react with oxygen in order to react with oxygen in contained in glass for generating a strong bond. However, it is very difficult to industrially use alkali metals, etc. which react vigorously with, for example, moisture in the atmosphere. Moreover, if the metal of the bonding layer is completely melted within a range of 300° C. to 500° C., which is a typical bonding temperature range, the melted metal may run over. For this reason, in the present invention, a metal having a melting point of 500° C. or more may be used. Metals satisfying the above are Al, Ti, Cr, W, Mo, Hf, Zr, V, Mg, and Fe.

Next, an easily oxidizable property of those metals will be described in detail. Reaction equations representing oxidization of those metals are shown as follows.

2Al+3/2O₂—Al₂O₃ (1)

Ti+O₂—TiO₂ (2)

2Cr+3/2O₂→Cr₂O₃ (3)

W+O₂→WO₂ (4)

Mo+O₂→MoO₂ (5)

Hf+O₂→HfO₂ (6)

Zr+O₂→ZrO₂ (7)

V+O₂→VO₂ (8)

Mg+O₂→MgO₂ (9)

2Fe+3/2O₂→Fe₂O₃ (10)

Next, if standard generation free energy is calculated by using standard generation entropy and standard generation enthalpy of various oxides according to Tables in the end of MATERIALS THERMOCHEMISTRY Sixth Edition (Pergamon Press) written by Kubaschewski, it becomes as follows.

| | | |
|---|---|---|
| (1) | Al₂O₃ | −1690 kJ/mol |
| (2) | TiO₂ | −960 kJ/mol |
| (3) | Cr₂O₃ | −608 kJ/mol |
| (4) | WO₂ | −604 kJ/mol |
| (5) | MoO₂ | −601 kJ/mol |
| (6) | HfO₂ | −1135 kJ/mol |
| (7) | ZrO₂ | −1115 kJ/mol |
| (8) | VO₂ | −727 kJ/mol |
| (9) | MgO₂ | −609 kJ/mol |
| (10) | Fe₂O₂ | −849 kJ/mol |

This represents that reaction to generate various oxides (that is, reaction in right direction) in the above-mentioned reaction equations (1) to (10) easily occur since the free energy decreases greatly due to the reaction.

Metals other than the above which are easily oxidizable exist but those metals may excessively react with moisture in the atmosphere or melt during heating, which causes problems for industrially managing, or some metals are not easily oxidized. For this reason, those metals are excluded.

Moreover, a structure when the above-mentioned metals are used to form bonding layers on a ceramic substrate or nonoxidized semiconductor is as follows.

A metal, which has a high adherence property to ceramics, etc., is empirically Ti or Cr. It is considered that these metals obtain excellent adhesion since the reactiveness with the element contained in ceramics is high. Since Ti or Cr is easily oxidizable and can be bonded with glass, a single metallized layer can be bonded with glass. On the other hand, other metals, Al, W, Mo, Hf, Zr, V, Mg, and Fe may not obtain an excellent bond with ceramics alone. In this case, Ti or Cr is used to form an adhering layer, and a metallized layer of Al, W, Mo, Hf, Zr, V, Mg, and Fe is formed thereon as a bonding layer. This structure makes it possible to satisfy anodic bonding with glass and adherence of a metallized layer to a ceramic substrate, etc.

In this embodiment, a form in which the electronic circuit module 50 is mounted on the circuit substrate 27 as shown in FIG. 9 is illustrated. However, it is also possible to mount the electronic circuit module on, for example, a lead frame and to mold the whole with resin.

### INDUSTRIAL APPLICABILITY

The present invention can be mainly applied to an accumulating and packaging technology of SiC semiconductors and sub-mount parts for optical devices.

What is claimed is:

1. An electronic component union in which a first substrate and a second substrate are bonded together by anodic bonding,
wherein the first substrate is formed of an insulating material or a nonoxidized semiconductor and has a conductive film on at least a surface of the first substrate facing the second substrate;
the second substrate is composed of a glass substrate which contains positive ions capable of being diffused by voltage application; and
the second glass substrate is bonded with the first substrate with the conductive film interposed therebetween by anodic bonding.

2. The electronic component union according to claim 1, wherein the second substrate is composed of a composite substrate in which a silicon substrate is bonded to the glass substrate in advance by anodic bonding.

3. The electronic component union according to claim 1, wherein the insulating material forming the first substrate is ceramics.

4. The electronic component union according to any one of claims 1 to 3, wherein the conductive film provided on the first substrate is composed of two layers an adhering layer and a bonding layer accumulated thereon, the adhering layer contains at least Ti, and the bonding layer contains at least Al.

5. The electronic component union according to any one of claims 1 to 3, wherein a metal of at least a surface, facing the second substrate, of the conductive film provided on the first substrate contains, as a main component, at least one selected from a metal element group of Al, Ti, Cr, W, Mo, Hf, Zr, V, Mg, and Fe.

6. The electronic component union according to any one of claims 1 to 3, wherein conductive films are provided on a top surface and a bottom surface of the first substrate and the conductive films on the top surface and the bottom surface are electrically connected to each other by through holes, having conductive films formed on the internal surfaces, of the substrate.

7. The electronic component union according to any one of claims 1 to 3, wherein, in the first substrate, a conductive film is continuously formed from the top surface of the substrate to at least a peripheral portion of the bottom surface, and the conductive films on the top surface and the bottom surface are electrically connected to each other by the conductive film formed on side surfaces of the substrates.

8. An electronic component union in which a union of a first substrate and a second substrate is used as a sub-mount for mounting an optical device, wherein a ceramic substrate in which a conductive film has been formed on a portion of a surface is used as the first substrate, a glass substrate in which a slope for reflecting light has been formed is used as the second substrate, and the second glass substrate is bonded to the first substrate with the conductive film formed on the surface of the first substrate by anodic bonding.

9. The electronic component union according to claim 8, wherein a bonding substrate of Si and glass having the slope formed by etching is used as the second substrate and the conductive film of the first substrate and the glass of the second substrate are bonded together by anodic bonding.

10. The electronic component union according to claim 8 or 9, wherein a metal of at least a surface, facing the second substrate, of the conductive film provided on the first substrate contains, as a main component, at least one selected from a metal element group of Al, Ti, Cr, W, Mo, Hf, Zr, V, Mg, and Fe.

11. An electronic circuit module in which a union of a first substrate and a second substrate is used as a semiconductor component, wherein a nonoxidized semiconductor substrate is used as the first substrate, a substrate in which borosilicate glass and silicon are bonded together in advance is used as the second substrate, electronic circuits are formed on one surface of the nonoxidized semiconductor substrate which is the first substrate, a conductive film is formed on the other surface of the nonoxidized semiconductor substrate, electronic circuits are formed on a silicon surface of the second substrate, and the conductive film formed on the surface of the nonoxidized semiconductor substrate which is the first substrate is bonded to the borosilicate glass of the second substrate by anodic bonding.

12. The electronic component union according to claim 11, wherein the nonoxidized semiconductor substrate which is the first substrate is a substrate formed of a silicon carbide semiconductor or any one of compound semiconductors consisting of a III-V group or a II-VI group.

13. The electronic component union according to claim 11 or 12, wherein a metal of at least a surface, facing the second substrate, of the conductive film provided on the first substrate contains, as a main component, at least one selected from a metal element group of Al, Ti, Cr, W, Mo, Hf, Zr, V, Mg, and Fe.

14. A method of manufacturing an electronic component union in which a first substrate formed of an insulating material or a nonoxidized semiconductor and a second substrate composed of a glass substrate overlap each other and are bonded together by anodic bonding, the method comprising:
forming a conductive film on at least a surface, facing the second substrate, of the first substrate, the conductive film containing, as a main component, at least one selected from a metal element group of Al, Ti, Cr, W, Mo, Hf, Zr, V, Mg, and Fe;
superimposing the glass substrate which contains positive ions capable of being diffused by voltage application as the second substrate on the conductive film of the first substrate; and
performing anodic bonding between the substrates by applying a DC voltage cross to at least the conductive film and the glass substrate in a state in which the superimposed substrates have been heated to at least 200° C.

15. The method of manufacturing an electronic component union according to claim 14, wherein, in the forming of the conductive film, the conductive film is formed to have a thickness of at least 0.01 μm, and in the performing of the anodic bonding, the anodic bonding is performed by applying a DC voltage of 200 V to 1000 V in a state in which the substrates have been heated to 300° C. to 500° C.
